(19) United States
(12) Patent Application Publication
(10) Pub. No.: US 2026/0138474 A1
(43) Pub. Date: May 21, 2026

(54) CHARGING DEVICE INTEGRATED INTO A KERB, KERBSTONE OR PAVING STONE, FOR CHARGING AN ENERGY STORE OF AN ELECTRICALLY DRIVEN VEHICLE

(71) Applicant: PIERBURG GMBH, NEUSS (DE)

(72) Inventors: FELIX STRACKE, NEUSS (DE); AXEL HEMSING, NEUSS (DE); JENS HOFFMANN, NEUSS (DE); ANDREAS BRETZ, NEUSS (DE); FRANK BUERGER, NEUSS (DE)

(73) Assignee: PIERBURG GMBH, NEUSS (DE)

(21) Appl. No.: 19/121,432

(22) PCT Filed: Dec. 23, 2022
(86) PCT No.: PCT/EP2022/087811

§ 371 Date: Apr. 16, 2025

(30) Foreign Application Priority Data
Oct. 21, 2022 (WO) PCT/EP2022/079362

(51) Int. Cl. B60L 53/31; B60L 53/16; E01C 11/22; H05B 1/02; H05B 3/04; H05B 3/44; H05B 6/06; H05B 6/10; H05K 5/06

(52) U.S. Cl. CPC B60L 53/31; B60L 53/16; E01C 11/223; H05B 1/0236; H05B 3/04; H05B 3/44; H05B 6/06; H05B 6/10; H05K 5/069; H05B 2214/02

(57) ABSTRACT

A curb stone or paving stone charging device for charging an energy store of an electrically driven vehicle. The curb stone or paving stone charging device includes a main body, an inner receiving space which is delimited on a plurality of sides by the main body, a cover which closes the receiving space, a charging unit having components which are arranged in the receiving space, a charging socket which is connected mechanically at least indirectly to the cover, and a heating element which heats the cover. The main body is produced from a metal, a concrete, a natural stone, a plastic or a composite material.

### CROSS REFERENCE TO PRIOR APPLICATIONS

This application is a U.S. National Phase application under 35 U.S.C. § 371 of International Application No. PCT/EP2022/087811, filed on Dec. 23, 2022 and which claims benefit to International Patent Application No. PCT/EP2022/079362, filed on Oct. 21, 2022. The International Application was published in German on Apr. 25, 2024 as WO 2024/083349 A1 under PCT Article 21(2).

### FIELD

The present invention relates to a curbstone or paving stone charging device for charging an energy store of an electrically driven vehicle, the curbstone or paving stone charging device having a main body which is made of a metal, concrete, natural stone, plastic or composite material, an inner receiving space which is delimited on a plurality of sides by the main body, a cover via which the receiving space is closed, components of a charging unit which are arranged in the receiving space, and a charging socket which is connected mechanically at least indirectly to the cover.

### BACKGROUND

Curbstone or paving stone charging devices of this type are charging stations which are integrated in the curbstone or paving stone and to which vehicles can be connected via an electrical connection in order to charge their energy stores or their batteries. This in particular relates to purely electrically driven vehicles but also hybrid vehicles. Chargeable vehicles can be passenger cars, trucks, motorcycles or electric bicycles.

As a result of new legislation, the increasing interest of the population in climate protection, and the improved profitability of electrified vehicles, it is to be expected that the proportion of electric vehicles will increase, in particular in the inner-city areas, with the result that the available charging infrastructure must be greatly expanded, which in turn means that some of the available parking spaces must be provided with corresponding charging possibilities in order to provide for individual mobility in the future.

Known concepts for this purpose provide the use of streetlamps, and additional charging columns or wall boxes on house walls. In all of these concepts, additional space requirement arises, and the pedestrians are disturbed by the charging cables to be used.

For this reason, charging systems have become known where the charging devices are integrated in the curbstone or in the paving stone. This has the advantage that no charging columns block the sidewalks and thus disturb the visual impression. No additional space requirement exists, but rather only existing infrastructure is used. A high degree of flexibility and retrofitability exists as a result of possible modularization. Damage to the charging infrastructure as a result of accidents with vehicles can also be prevented.

A special configuration of such a curbstone with electronics for charging a vehicle is described in WO 2021/156621 A1. This curbstone is of modular construction and has a base element into which an exchangeable receiving container is insertable. The components for electrically charging a battery of a vehicle are arranged in this container. The receiving container is open at the top and is closed by a cover which delimits the base element towards the road via an obliquely formed wall. The base element and also the container and the cover are produced from plastic. Embodiments in which components can be extended out of the cover are also known therefrom.

A problem with a curbstone of this type is that the mobility of the parts is restricted in the event of precipitation and temperatures below 0° C. The covers can also freeze in the case of embodiments with a fixedly installed charging socket. This curbstone also has no arrangements via which the amount of energy emitted or a status can be read. In the event of relatively heavy snowfall, such curbstones can possibly even no longer be found at all and entail a risk of slipping. Problems can also arise during the authentication.

### SUMMARY

The aspect of the present invention is to provide a curbstone or paving stone charging device for charging an energy store of an electrically driven vehicle via which a winter operation can reliably be carried out. Both the mobility of the parts which can be moved relative to one another and a free visibility of displays are to be provided in this case. The operability and accessibility of the charging sockets must also to be provided.

In an embodiment, the present invention provides a curbstone or paving stone charging device for charging an energy store of an electrically driven vehicle. The curbstone or paving stone charging device includes a main body, an inner receiving space which is delimited on a plurality of sides by the main body, a cover which is configured to close the receiving space, a charging unit comprising components which are arranged in the receiving space, a charging socket which is connected mechanically at least indirectly to the cover, and a heating element which is configured to heat the cover. The main body is produced from a metal, a concrete, a natural stone, a plastic or a composite material.

### BRIEF DESCRIPTION OF THE DRAWINGS

The present invention is described in greater detail below on the basis of embodiments and of the drawings in which:

FIG. 1 shows a schematic sketch of a road with a delimiting curbstone charging device in a plan view;

FIG. 2 shows a perspective view of a curbstone charging device according to the present invention with heating elements, illustrated by dashed lines, in the form of a resistance wire and a fixed charging socket;

FIG. 3 shows a side view of a curbstone charging device according to the present invention with resistance wire in a sectional illustration;

FIG. 4 shows a perspective view of a curbstone charging device according to the present invention with heating elements, illustrated by dashed lines, in the form of a resistance wire and a pivotable charging socket;

FIG. 5 shows a side view of a curbstone charging device according to the present invention with a heating mat in a sectional illustration.

### DETAILED DESCRIPTION

A curbstone or paving stone charging device according to the present invention for charging an energy store of an electrically driven vehicle has a main body which is produced from a concrete, natural stone, plastic or composite material, for example, by casting. Concrete is of course also to be understood as meaning an ultra-high-strength concrete (UHPC), fiber-reinforced concrete, or a polymer concrete, in which a plastic is used as a binder instead of the binder cement. A receiving space which is delimited on a plurality of sides by the main body is formed in the interior of the main body. The main body in particular has a base and three or four side walls. The receiving space is closed by a cover which is placed, for example, onto the upwardly facing ends of the four side walls. The cover can, however, of course also form one or more side walls of the receiving space. Components of a charging unit which are fastened, for example, to the cover but which can also be fastened to the main body are arranged in the receiving space. These components of a charging unit can form both a completely autonomous charging unit which requires only one power connection and contains all electronic components and can also be present individually and can serve in any desired manner for controlling or for protecting the charging socket and the charging process. Individual electronic components of the charging unit, such as an energy meter, charging controller, a protective contactor, or a transmitting and receiving unit for authentication, can correspondingly also be arranged in the receiving space. Components of the charging unit are thus understood to mean individual components or a plurality of components which can serve to charge the energy store of the electric vehicle or of the hybrid vehicle. The curbstone or paving stone charging device also has a charging socket which is connected mechanically at least indirectly to the cover. This mechanical connection can be realized via lifting or pivoting mechanisms or via additional parts fastened to the cover. This charging socket is of course electrically connected to the charging unit or to components of the charging unit.

The present invention provides that the cover can be heated via a heating element. Differently designed heating elements and also the use of a plurality of heating elements are here conceivable, wherein, because of the existing connection of the curbstone or paving stone charging device to a voltage source, in particular electrically operated heating elements can be used. Via the heating of the cover, parts which can be moved relative to one another and are on the cover, such as, for example, lifting or pivoting mechanisms, can be protected from jamming by ice formation or existing ice layers can be melted. This can be realized proactively or if necessary. Display units can furthermore be kept free of ice and snow so as to provide free visibility. The entire upper side can be kept free of ice and snow by heating the cover so that the curbstone also always remains accessible. The usability of the charging socket is also maintained and a socket cover which can be provided can be folded. Access to a transmitting and receiving unit for authentication can also be provided in this way. Such a curbstone or paving stone charging device can accordingly also be used completely under winter weather conditions. It is sufficient in this case, however, to heat the cover since the essential components for using the curbstone as a charging station are here arranged; heating over a relatively large area can thereby be avoided.

The cover can, for example, be made of metal, as a result of which good thermal conductivity is provided so that heating over the entire area via the heating element or elements does not need to be provided; even small heating areas can much rather be sufficient as a result of the thermal conduction.

A resistance wire can, for example, serve as the heating element. Such a resistance wire is also called a heating wire and is produced from a heating conductor alloy made of two or more metals which have a relatively high specific electrical resistance and have a low tendency to oxidation and whose object is accordingly to convert electrical energy into heat. Such a resistance wire requires almost no installation space and can simply be mounted to specific locations in order to introduce heat in a targeted manner. A resistance wire can also be operated cost-effectively with low voltages of, for example, 12 V and has a high temperature resistance.

In an embodiment of the present invention, the resistance wire can be integrated in a seal which is arranged between the cover and components connected to the cover. No additional insulation of the wire is thereby necessary and the heating element is introduced in an assembly step with the seals which are necessary anyway, with the result that additional assembly steps can be avoided. The heating of the cover if integrated into the seal between the main body and the cover is furthermore realized in this way from all sides, with the result that a rapid and complete heating of the cover is provided.

In an embodiment of the present invention, an electronics box and/or a charging socket are fastened to the cover, wherein the seal with the resistance wire is arranged between the flange faces of the electronics box and/or of the charging socket with respect to the cover. Both good visibility of a display unit, arranged in the electronics box, of an energy meter and free accessibility and functionality of the charging socket and free mobility of a socket cover which can be provided are correspondingly provided since the cover is heated by the resistance wire in the immediate vicinity of these critical components.

A groove, in which the resistance wire is arranged, can, for example, be formed in the cover or at the free ends of the side walls of the receiving space of the main body, which free ends are covered by the cover, or at a flange face of the electronics box, which flange face faces the cover. The resistance wire can either simply be inserted into the groove as an insulated resistance wire or can be inserted together with the seal. The cover is heated over a relatively large section in both cases, with the result that the critical locations of the cover which are to be heated can in particular be heated to the desired temperature in a short time in order to dissolve an ice layer or snow layer.

In an embodiment of the present invention, the groove can, for example, be formed circumferentially around an open side of the receiving space of the main body, which open side is closed by the cover. This circumferential configuration of the groove and of the resistance wire provides that the entire cover can be heated to a desired temperature in a short time in order to free it of ice and snow.

It is particularly advantageous if a seal, via which a gap between the main body and the cover is sealed, is arranged in the groove in addition to the resistance wire. Both the seal of the cover and the heating element can thus be introduced in one assembly step.

The resistance wire can, for example, be insulated, with the result that electrically conductive contact with the surrounding housing is avoided.

It is particularly advantageous if the resistance wire is fastened via a thermally conductive adhesive. This can be realized in the groove or in a planar manner on the cover. The thermal conduction to the cover is thus improved and the heating times are shortened.

In an embodiment of the present invention, the heating element extends around a receiving opening of the charging socket. The functionality of the charging socket at temperatures below the freezing point is thus provided since ice layers are dissolved. A socket cover which can be provided can thus simply be folded open and icing of the charging socket itself is avoided, with the result that problems when inserting the plug into the charging socket are avoided.

It is also advantageous if the heating element extends around a receiving opening in which a transmitting and receiving unit, in particular in the form of an RFID antenna, is received. The communication between the user and the charging controller or the server of the provider can thus also be provided in the case of ice and snow.

The charging socket can, for example, also be moved out of an opening on the cover via a pivoting part, wherein the heating element extends around the opening from which the pivoting part is pivoted out of the cover. Such a pivoting socket has the advantage that the user can access it better and the charging socket is arranged in the receiving space in a protected manner outside the charging process. The heating element provides that an ice layer which can be present in the gap between the cover and the pivoting part is dissolved or cannot grow at all, with the result that the functionality is provided under all weather conditions.

In order also to provide the legal provisions of a possible readability of the energy meter at any time, the charging unit is provided with an energy meter which has a display unit which can be read through an opening or an inspection window in the cover, wherein the opening or the inspection window is at least partially surrounded by the heating element. The inspection window of the display unit thus always remains visible.

In an embodiment of the present invention, a temperature sensor can, for example, be arranged in the cover, via which temperature sensor a temperature of the cover can be measured. Outside temperatures can be determined via the temperature sensor outside of heating times. It can thus be determined whether ice formation is to be expected. The temperature of the cover can at the same time be measured during the heating, and the heating element or elements can accordingly be controlled.

A temperature sensor can furthermore, alternatively or additionally be arranged on the curbstone or paving stone charging device, via which temperature sensor an outside temperature can be measured so that a control can also be realized only as a function of the outside temperature.

The heating element is controlled as a function of the measured values of the temperature sensor in order thus to reduce power consumption.

The temperature sensor and the heating element are electrically connected to a charging controller of the charging unit or a separate control unit for this purpose. Additional components can be omitted by using the charging controller of the charging unit for controlling the resistance wire via the measured values of the temperature sensor. The measured values of the temperature sensor can also be used for the charging control if desired.

It is also advantageous if the heating element can be controlled as a function of weather data which can be transmitted to a control unit or the charging controller of the heating element via a transmitting and receiving unit in the form of a radio interface of the curbstone or paving stone charging device. A temperature sensor can in this case optionally be omitted or the data can additionally be used. This also makes a preventive heating of the cover possible in order to avoid any formation of ice or snow on the curbstone, paving stone or paving stone.

In an alternative embodiment to the resistance wire, a heating mat or heating cartridge can be fastened to the cover as heating element. These heating mats usually consist of a plastic in which wires are embedded. Uniform and large-area heating of the cover can thus be realized. The heating cartridge is an electrically heated rod with which the entire receiving space can also be heated.

A radiant heater, in particular an infrared radiator, is alternatively arranged in the receiving space, which radiant heater generates a heat flow to the cover or irradiates the cover. Heating of the cover can thereby also be achieved over a large area.

It is also alternatively possible to arrange conducting elements in the receiving space, which conducting elements conduct the waste heat of a pivot drive, of a locking actuator of the charging socket or of the charging unit to the cover. The pivot drive or the locking actuator can be energized therefor, for example, without generating a movement, with the result that only lost heat arises. A targeted heating of the cover is likewise possible by conducting this heat to the cover via the conducting elements. The lost heat of the heat-generating parts of the charging unit can also accordingly be conducted to the cover via conducting elements and the latter can be heated accordingly.

Induction elements can alternatively be arranged on the cover via which induction heat is generated in the conductive cover, as a result of which sufficient heat for dissolving ice or snow layers can likewise be made available.

A heat pump, in particular an air heat pump for heating, is alternatively arranged in the receiving space.

A curbstone or paving stone charging device for charging an energy store of an electrically driven vehicle is thus provided via which charging device a complete functionality of the charging device is provided independent of weather conditions and temperatures below 0° C. This heating can be introduced in a targeted manner in critical regions, whereby the effort for assembly and the cost efforts are very low. The heating of the cover can here be realized only if necessary, i.e., for example, the pivoting part of a charging socket is already frozen and the ice must accordingly be melted, or temperature windows can be defined in which heating is performed preventively in order to avoid freezing in advance. A connection to the charging unit can also be realized in order to, for example, be able to communicate the current temperature of the cover or the operating state of the heating to the server of the service provider, or vice versa, to be able to communicate weather data from the server to the charging unit and thus to be able to control the heating elements as a function of these values.

A non-limiting exemplary embodiment of a curbstone or paving stone charging device according to the present invention for charging an energy store of an electrically driven vehicle is described below based on the example of a curbstone charging device.

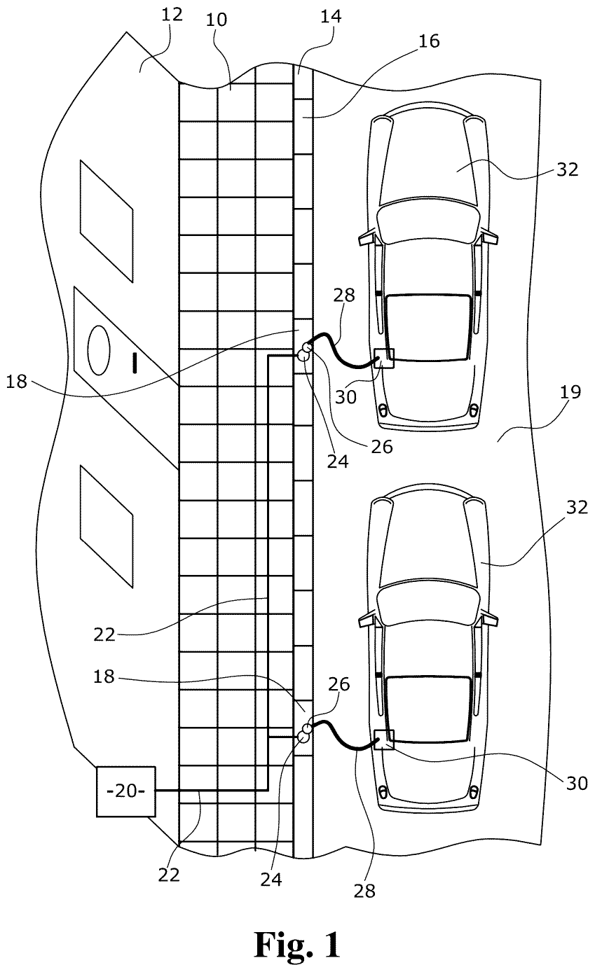

FIG. 1 illustrates a walkway 10 which is delimited on its one side by a house wall 12 and on the other side by a curbstone edge 14 which is formed by a plurality of stone elements 16 and curbstone or paving stone charging devices 18 according to the present invention and forms a boundary with respect to the road 19. On that side of the walkway 10 which faces away from the curbstone edge 14, there is an energy source 20 in the form of a power connection which is connected to the power grid. The energy source 20 is connected to the curbstone or paving stone charging devices 18 via underground energy supply cables 22. Charging sockets 24 are arranged on the curbstone or paving stone charging devices 18, into which charging sockets a plug 26 is plugged which is connected via a cable 28 to an energy store 30, in particular a battery of an electrically operated vehicle 32, with the result that this energy store 30 can be charged via the energy source 20.

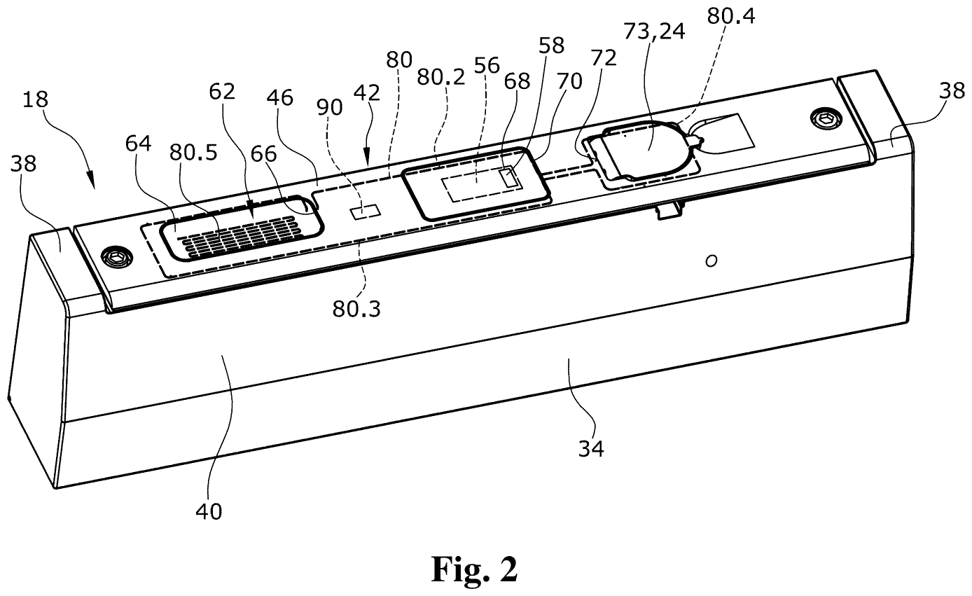

A curbstone or paving stone charging device 18 according to the present invention is illustrated in FIG. 2. Below, the terms “at the top”, “at the bottom”, “below”, “above” or the like in each case mean the state of the curbstone or paving stone charging devices 18 which corresponds to the state which is installed at the road edge. An “upper side” thus corresponds to that side which faces away from the earth surface in the installed state.

The curbstone or paving stone charging device 18 according to FIG. 2 consists of a main body 34 which is produced from a steel, a concrete or a plastic or a composite material and can contain fiber reinforcements. This main body 34 has a base 36, from which a total of two side walls 38, a front wall 40, and a rear wall 42 extend upwards, which walls serve as side walls 38, 40, 42 of a receiving space 44 which is formed in the interior of the main body 34. This receiving space 44 is closed by a cover 46, the outer circumference of which rests on the free upwardly facing ends 47 of the side walls 38, 40, 42.

An electronics box 48 which is fastened to the cover 46 via a flange surface 50 and in which components of a charging unit 52 are arranged is arranged in the interior of the receiving space 44. In addition to a charging controller 54 as a component, this charging unit 52 has a combined residual current and line protection switch 55 which is connected to an energy meter 56 with a display unit 58 which is connected to the charging socket 24 with the interconnection of a protective contactor 59. A power supply unit 60 is furthermore arranged in the electronics box 48, via which power supply unit 60 the high-voltage voltage which is present is converted into a low-voltage, in particular a voltage of 12 V. The power supply of the charging controller 54 is realized via the power supply unit 60, via which charging controller 54 a protective contactor is switched, which protective contactor is also arranged in the electronics box 48. Before the switching of the protective contactor 59 via the charging controller 54, switching of a locking actuator 61 of the charging socket 24 and beforehand authentication of the user via a transmitting and receiving unit 62, for example, in the form of an RFID antenna, is necessary, which RFID antenna is arranged under a plastic cover 64 which closes a first opening 66 in the cover 46. In the present case, the charging controller 54, the combined residual current and line protection switch 55, the energy meter 56, the protective contactor 59, the power supply unit 60, and the transmitting and receiving unit 62, are components of the charging unit 52.

The display unit 58 of the energy meter 56 is located under an inspection window 68 which is arranged in a second opening 70 on the cover 46. A third opening 72 is located on the cover 46 for receiving the charging socket 24, which third opening 72 is covered by a socket cover 73 which rests against the cover 46 with a flange face 74 with the interposition of a seal 75.

In an alternative embodiment, a pivoting part 76 of a pivotable charging socket 24 is arranged in this third opening 72, which pivoting part 76 closes the third opening 72 outside the charging times and is pivoted out of the third opening 72 with the charging socket 24 before the start of the charging process. The pivoting part 76 can be configured to be somewhat larger than the third opening 72 and to rest on an outer edge of the third opening 72 between the charging processes. For this purpose, the cover 46 and the pivoting part 76 can be designed to be somewhat thinner in the region where they lie on top of each other and to have shoulders which correspond to one another so that a smooth surface results. The pivoting process is carried out by a pivot drive 78, which pivot drive 78 in particular has an electric motor, and by the pull and push rod of which being connected to the pivoting part 76.

A plurality of heating elements 80 are arranged on the cover 46 in order to provide that the moving parts remain movable even in the case of frost and ice formation, that the display unit 58 can also be read in the case of snow, that the transmitting and receiving unit 62 remains accessible for radio waves, and that the charging socket 24 remains accessible and functional.

It is here pointed out that these heating elements 80 can either all be used, or that only a single one or a plurality of the heating elements 80 in the sense of the present invention can be used.

A circumferential groove 82 thus is formed on the cover 46, namely, on the side of the cover 46 and in the region which rests on the ends 47 of the side walls 38, 40, 42. An insulated first electrical resistance wire 80.1 as a heating element 80 and a first circumferential seal 84 for sealing a gap 85 between the cover 46 and the side walls 38, 40, 42 are arranged in this circumferential groove 82. The first electrical resistance wire 80.1 rests directly on the cover 46 in the circumferential groove 82, while the first circumferential seal 84 rests on the ends 47 of the side walls 38, 40, 42 for sealing. The first electrical resistance wire 80.1 is fastened to the cover 46 via a thermally conductive adhesive in the circumferential groove 82. It would, however, likewise be conceivable to integrate the first electrical resistance wire 80.1 in the first circumferential seal 84.

A second electrical resistance wire 80.2 is attached to the cover 46 from the inside, for example, via the thermally conductive adhesive, and surrounds the inspection window 68 of the display unit 58 of the energy meter 56.

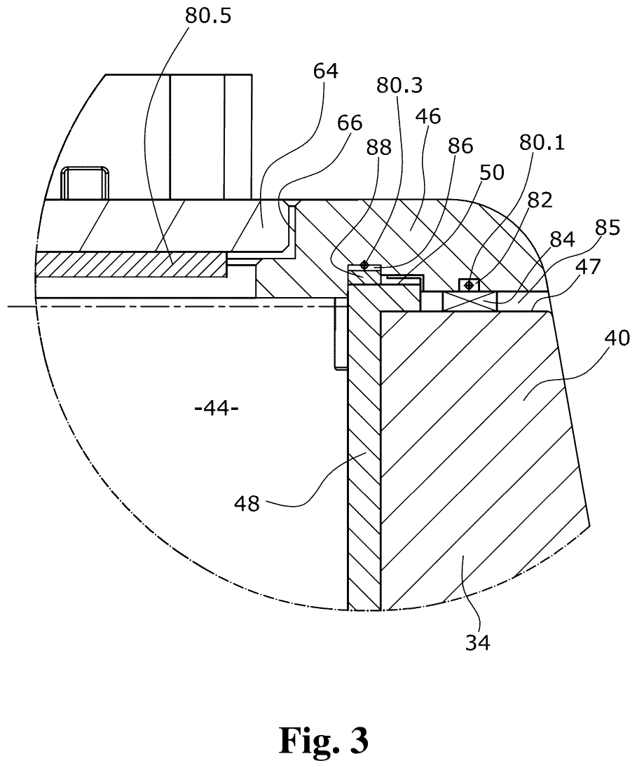

As illustrated in FIG. 3, a third electrical resistance wire 80.3 is located in a groove 86 on that side of the cover 46 which faces the flange surface 50 of the electronics box 48, in which groove a seal 88 is also arranged.

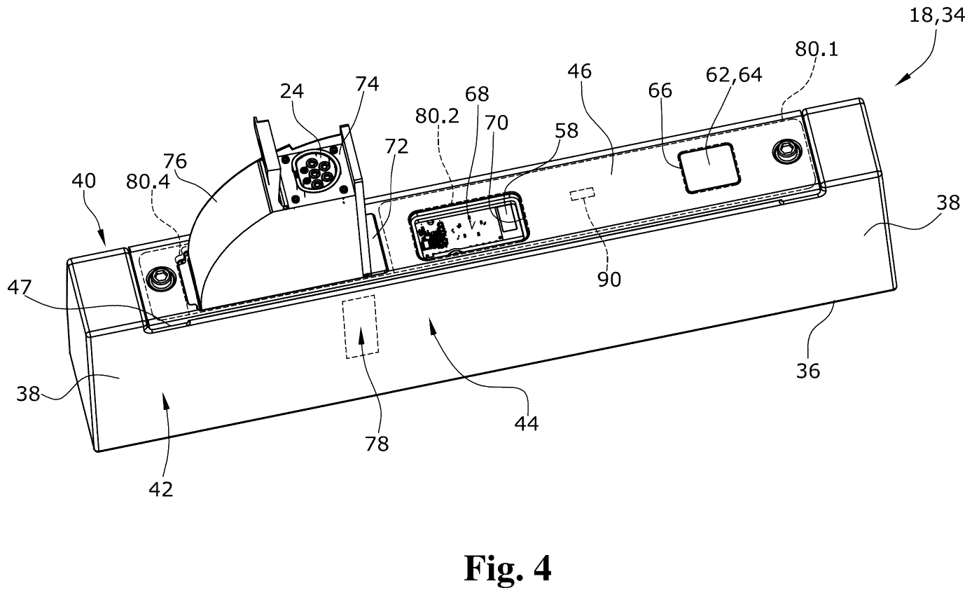

A fourth electrical resistance wire 80.4 is arranged both in the variant with the pivoting part 76 of the charging socket 24 according to FIG. 4 and in the variant of the fixed charging socket 24, in the region of the cover 46 according to FIG. 2 which fourth electrical resistance wire 80.4 surrounds the third opening 72, wherein, in the case of the fixed variant, the fourth electrical resistance wire 80.4 is clamped between the flange face 74 of the charging socket 24 and the cover 46.

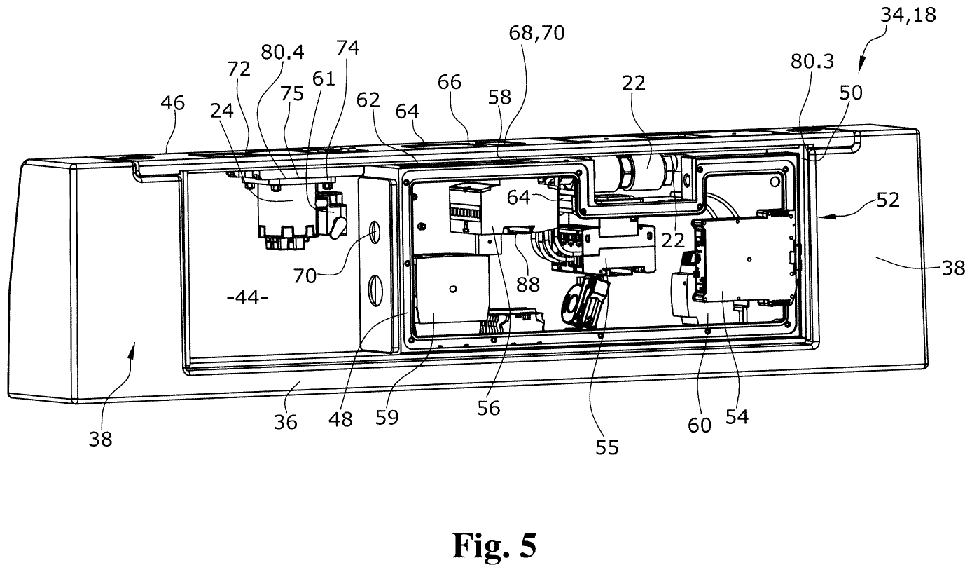

It is furthermore illustrated in FIG. 5 that a heating mat 80.5 is fastened below the plastic cover 64 of the transmitting and receiving unit 62.

All critical locations which must either be accessible, visible or movable for the function of the charging device can be heated via the heating elements 80 so that a build-up of a snow layer and an ice layer can either be prevented or can be dissolved prior to the charging process.

A temperature sensor 90 is arranged on the underside of the cover 46 in order to control this heating. The temperature sensor 90 is electrically connected to the charging controller 54 or a separate control unit to which the heating elements 80 are also all connected. The heating elements 80 can correspondingly either be heated preventively or heated prior to the use of the charging device when the temperature falls below a critical temperature of, for example, 4° C., wherein the temperature of the cover 46 can then be monitored in order to decide on the dissolution of the snow layers or ice layers via stored characteristic maps. It is also possible to communicate weather data to the charging controller via the transmitting and receiving unit 62 and to initiate the heating thereby, which heating can be checked via the temperature sensor 90 in order to carry out the control of the energization of the heating elements 80 accordingly.

The complete charging infrastructure can be created in a simple manner via the curbstone charging devices described for charging an energy store of an electrically driven vehicle, which charging infrastructure has a flexible and modular construction and the functionality thereof is provided under all weather conditions.

It should furthermore be clear that the heating elements can be adapted to the respective circumstances. All the heating elements described must not necessarily be used since a single heating element on the cover can optionally also be sufficient. In addition to the resistance wires and heating mats described, radiant heaters, such as infrared radiators, which irradiate the cover, or heating cartridges can also be used. The pivot drive or the heat-generating components of the charging unit can also be used as a heating element, and the waste heat thereof can be conducted in the direction of the cover via conducting elements.

The present invention is not limited to embodiments described herein; reference should be had to the appended claims.

### LIST OF REFERENCE NUMERALS

10 Walkway
12 House wall
14 Curbstone edge
16 Stone element
18 Curbstone or paving stone charging device
19 Road
20 Energy source
22 Underground power supply cable
24 Charging socket
26 Plug
28 Cable
30 Energy store
32 Electrically operated vehicle
34 Main body
36 Base (of main body 34)
38 Side wall (of main body 34)/Side wall (of receiving space 44)
40 Front wall (of main body 34)/Side wall (of receiving space 44)
42 Rear wall (of main body 34)/Side wall (of receiving space 44)
44 Receiving space
46 Cover
47 End (of the side walls 38, 40, 42)
48 Electronics box
50 Flange surface
52 Charging unit
54 Charging controller
55 Line protection switch
56 Energy meter
58 Display unit
59 Protective contactor
60 Power supply unit
61 Locking actuator
62 Transmitting and receiving unit
64 Plastic cover
66 First opening
68 Inspection window
70 Second opening
72 Third opening
73 Socket cover
74 Flange face
75 Seal
76 Pivoting part
78 Pivot drive
80 Heating element
80.1 First electrical resistance wire
80.2 Second electrical resistance wire
80.3 Third electrical resistance wire
80.4 Fourth electrical resistance wire
80.5 Heating mat
82 Circumferential groove
84 First circumferential seal
85 Gap
86 Groove
88 Seal
90 Temperature sensor

What is claimed is:

1-25. (canceled)

26. A curbstone or paving stone charging device for charging an energy store of an electrically driven vehicle, the curbstone or paving stone charging device comprising:
a main body which is produced from a metal, a concrete, a natural stone, a plastic or a composite material;
an inner receiving space which is delimited on a plurality of sides by the main body;
a cover which is configured to close the inner receiving space;
a charging unit comprising components which are arranged in the inner receiving space;
a charging socket which is connected mechanically at least indirectly to the cover; and
a heating element which is configured to heat the cover.

27. The curbstone or paving stone charging device as recited in claim 26, wherein the heating element is provided as a resistance wire.

28. The curbstone or paving stone charging device as recited in claim 27, further comprising:
a first seal,
wherein,
the components of the charging unit are connected to the cover,
the first seal is arranged between the cover and the components connected to the cover, and
the resistance wire is integrated in the first seal.

29. The curbstone or paving stone charging device as recited in claim 28, wherein:
the cover comprises at least one groove in which the resistance wire is arranged,
the inner receiving space is delimited on the plurality of sides by the main body via side walls which comprise free ends, and
the at least one groove is arranged in the cover so that the free ends of the side walls are covered by the cover of the inner receiving space of the main body, or the at least one groove is arranged in the cover so as to face the flange face of the electronics box.

30. The curbstone or paving stone charging device as recited in claim 29, wherein,
the at least one groove is formed circumferentially around an open side of the inner receiving space, and
the open side is closed by the cover.

31. The curbstone or paving stone charging device as recited in claim 30, further comprising:
a second seal which is arranged in at least one of the at least one groove in addition to the resistance wire, the second seal being configured to close a gap between the main body and the cover.

32. The curbstone or paving stone charging device as recited in claim 27, wherein the resistance wire is fastened within the heating element via a thermally conductive adhesive.

33. The curbstone or paving stone charging device as recited in claim 26, wherein,
the cover comprises a first opening for receiving the charging socket, and
the heating element is arranged to extend around the first opening.

34. The curbstone or paving stone charging device as recited in claim 33, further comprising:
a pivoting part,
wherein,
the charging socket is configured to be moved out of the first opening via the pivoting part.

35. The curbstone or paving stone charging device as recited in claim 34, wherein,
the cover further comprises a second opening or an inspection window,
the components of the charging unit includes an energy meter which comprises a display unit which is arranged to be readable through the second opening or through the inspection window, and
the second opening or the inspection window is at least partially surrounded by the heating element.

36. The curbstone or paving stone charging device as recited in claim 35, further comprising:
a first temperature sensor which is arranged in the cover, the first temperature sensor being configured to measure a temperature of the cover.

37. The curbstone or paving stone charging device as recited in claim 36, further comprising:
a second temperature sensor which is arranged on the curbstone or paving stone charging device, the second temperature sensor being configured to measure an outside temperature.

38. The curbstone or paving stone charging device as recited in claim 37, wherein the heating element is further configured to be controlled as a function of at least one of a measured value of the first temperature sensor and of a measured value of the second temperature sensor.

39. The curbstone or paving stone charging device as recited in claim 34, further comprising:
a transmitting and receiving unit,
wherein,
the cover further comprises a third opening for receiving the transmitting and receiving unit.

40. The curbstone or paving stone charging device as recited in claim 39, further comprising:
a separate control unit,
wherein,
the components of the charging unit include a charging controller,
the transmitting and receiving unit is configured to transmit weather data to the charging controller or to the separate control unit, and
the heating element is further configured to be controlled as a function of the weather data.

41. The curbstone or paving stone charging device as recited in claim 34, further comprising:
a pivot drive which is connected to the pivoting part, and
conducting elements which are arranged in the inner receiving space,
wherein,
the charging socket comprises a locking actuator, and
the conducting elements are configured to conduct a waste heat of the pivot drive, a waste heat of the locking actuator, or a waste heat of the charging unit to the cover.

42. The curbstone or paving stone charging device as recited in claim 26, wherein,
the heating element is provided as a heating mat or as a heating cartridge, and
the heating mat or the heating cartridge is fastened to the cover.

43. The curbstone or paving stone charging device as recited in claim 26, wherein the heating element is provided as an infrared radiator which is arranged in the inner receiving space, the infrared radiator being configured to irradiate the cover.

44. The curbstone or paving stone charging device as recited in claim 26, further comprising;
induction elements which are arranged on the cover, the induction elements being configured to generate an induction heat in the cover.

45. The curbstone or paving stone charging device as recited in claim 26, further comprising:
a heat pump which is arranged in the inner receiving space.
